(19) United States
(12) Patent Application Publication
(10) Pub. No.: US 2013/0050910 A1
(43) Pub. Date: Feb. 28, 2013

(54) FLASH DRIVE

(71) Applicant: WEI PANG, Shenzhen City (CN)

(72) Inventor: WEI PANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/232,986

(22) Filed: Sep. 14, 2011

(30) Foreign Application Priority Data
Aug. 31, 2011 (CN) 201110254643.5

(51) Int. Cl. H05K 5/00

(52) U.S. Cl. 361/679.01

(57) ABSTRACT

A flash drive includes a casing and a main body slidably received in the casing. A universal serial bus (USB) connector mounted to an end of the main body may be extended from and retracted into the casing.

### BACKGROUND

1. Technical Field

The present disclosure relates to a flash drive.

2. Description of Related Art

A casing for protecting a universal serial bus (USB) connector of a flash drive generally is separable from the flash drive. As a result, the casing may be lost easily.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a flash drive having a main body.

FIG. 2 is an exploded, isometric view of the main body of FIG. 1.

FIG. 3 is an isometric view of the flash drive of FIG. 1.

FIG. 4 is similar to FIG. 3, but showing another state of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

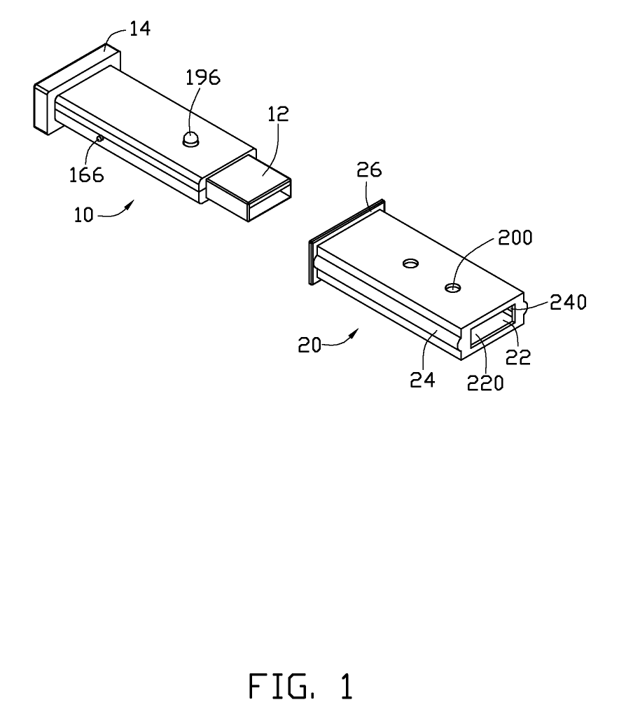

Referring to FIG. 1, an exemplary embodiment of a flash drive includes a main body 10, and a casing 20.

The casing 20 is substantially hollow and rectangular, and defines a receiving space 22. The receiving space 22 includes two opposite openings 220 defined in opposite ends of the casing 20. A flange (blocking portion 26) extends out perpendicularly from one of the ends of the casing 20. Two protrusions 24 extend the length of the casing 20, along the sides. A slide slot 240 communicating with the receiving space 22 is longitudinally defined in the inner surface of each protrusion 24. Two engaging holes 200 are defined in the top of the casing 20 and each communicates with the receiving space 22. One of the engaging holes 200 is adjacent to the blocking portion 26, and the other engaging hole 200 is adjacent to the other end of the casing 20.

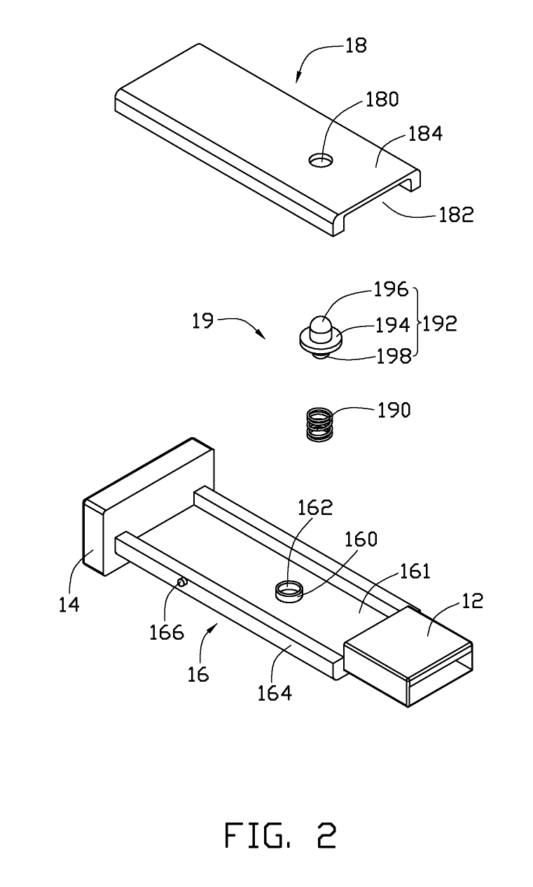

Referring to FIG. 2, the main body 10 includes a holder 16, a cover 18, and a fixing member 19. A universal serial bus (USB) connector 12 and an operation portion 14 extend from opposite ends of the holder 16. The holder 16 includes a bottom wall 161 and two sidewalls 164 extending up. A post 160 extends up from the bottom wall 161, and medially defines a receiving hole 162. A projection 166 protrudes from each of the outer surfaces of the sidewalls 164. The distal end of each projection 166 is hemispherical. The cover 18 includes a top wall 184 and two sidewalls (not labeled) extending down. The top wall 184 defines a through hole 180. A cutout 182 is defined in the cover 182. The fixing member 19 includes a fixing portion 192 and a resilient member 190. The fixing portion 192 includes a round connection portion 194, a pin 196 and a pole 198 respectively extending from the top and bottom of the connection portion 194. In this embodiment, the resilient member 190 is a coil spring.

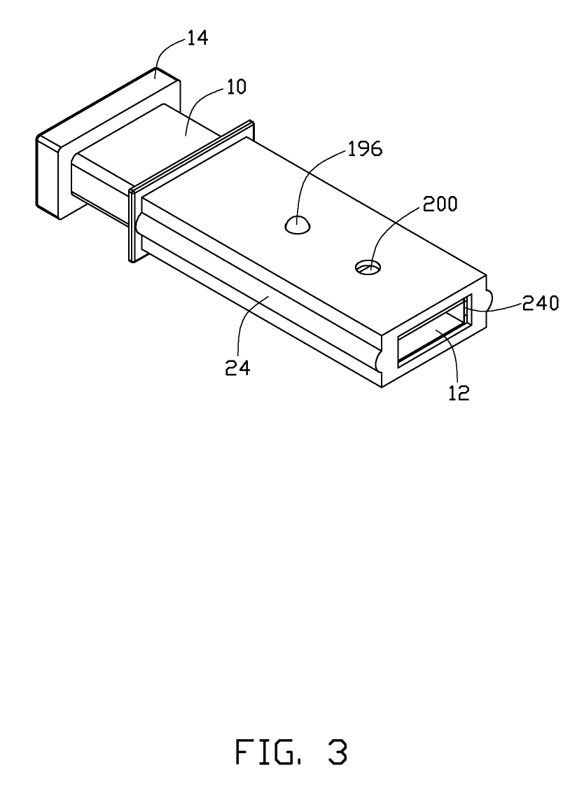

Referring to FIG. 3, in assembly, an end of the resilient member 190 fits closely about the pole 198 of the fixing portion 192 and contacts the bottom of the connection portion 194. The other end of the resilient member 190 is received in the receiving hole 162 and contacts the bottom wall 161. The cover 18 covers the holder 16.

When aligned, the pin 196 may extend through the through hole 180. The connection portion 194 is blocked by the inner surface of the top wall 184 when the pin 196 is in the through hole 180. The USB connector 12 extends through the cutout 182. The operation portion 14 abuts a second end of the cover 18 opposite to the cutout 182.

The end of the main body 10 with the USB connector 12 is inserted into the receiving space 22 through the opening 220 adjacent to the blocking portion 26. The main body 10 is slid toward the other opening 220. The pin 196 in the receiving space 22 is pressed up against the underside of the housing 20, the resilient member 190 being compressed. The projections 166 are slidably engaged in the corresponding slide slots 240. When the main body 10 is moved to a position where the pin 190 is aligned with the engaging hole 200 adjacent to the blocking portion 26, the resilient member 190 drives the pin 196 to engage in the engaging hole 200. In this state, the USB connector 12 is completely received in the receiving space 22.

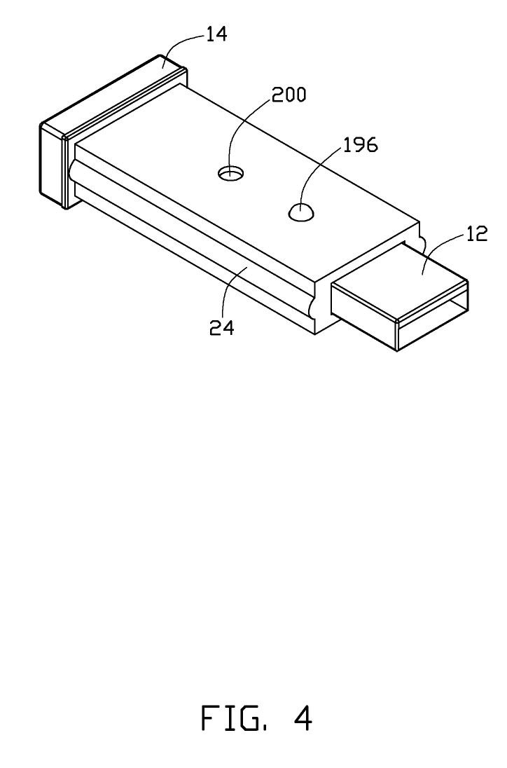

Referring to FIG. 4, when the USB connector 12 needs to be used, the pin 196 may be depressed by finger pressure to disengage from the engaging hole 200. The resilient member 190 is deformed further, and the operation portion 14 may be operated to slide the main body 10 relative to the housing 20. The operation portion 14 is moved toward the blocking portion 26. The USB connector 12 is then exposed out of the receiving space 22 through the corresponding opening 220. When the pin 196 is aligned with the other engaging hole 200, the resilient member 190 drives the pin 196 to engage in the other engaging hole 200. After use, the pin 196 is again depressed to disengage from the other engaging hole 200. The main body 10 may be slid with the operation portion 14 moving away from the blocking portion 26, to retract the USB connector 12 back into the receiving space 22, until the pin 196 is again engaged in the engaging hole 200 adjacent to the blocking portion 26.

In another embodiment, the existence of the blocking portion 26 is not crucial.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A flash drive, comprising:
a main body comprising a connector extending from a first end of the main body;
a fixing portion slidably mounted to the main body; and
a casing slidably fitting about the main body, wherein the slide direction of the casing relative to the main body is substantially perpendicular to the slide direction of the fixing portion, the casing defines an engaging hole;
wherein the casing is configured to slidably relative to the main body between a first position where the connector is received in the casing, and a second position where the fixing portion engages with the engaging hole and the connector is exposed out of the casing.

2. The flash drive of claim 1, wherein the connector is a universal serial bus connector.

3. The flash drive of claim 1, further comprising a resilient member connected between the main body and the fixing portion, to bias the fixing portion to slide to engage in the engaging hole.

4. A flash drive, comprising:
a main body comprising a connector extending from a first end of the main body;
a fixing portion slidably mounted to the main body; and
a casing slidably fitting about the main body, wherein the slide direction of the casing relative to the main body is substantially perpendicular to the slide direction of the fixing portion, the casing defines an engaging hole;
wherein the casing is operable to slide relative to the main body between a first position where the connector is covered in the casing and the fixing portion engages with the engaging hole, and a second position where the connector is exposed out of the casing.

5. The flash drive of claim 4, wherein the connector is a universal serial bus connector.

6. The flash drive of claim 4, further comprising a resilient member connected between the main body and the fixing portion, to bias the fixing portion to slide to engage in the engaging hole.

7. A flash drive, comprising:
a casing defining a receiving space having two opposite openings in two ends of the casing, and first and second engaging holes communicating with the receiving space; and
a main body slidably received in receiving space of the casing, the main body comprising a connector at a first end of the main body, and a fixing member, the fixing member comprising a fixing portion moveable relative to the main body along a direction perpendicular to the sliding direction of the main body;
wherein when the main body is slid to make the connector be received in the receiving space, the fixing portion engages in the first engaging hole; when the main body is slid to make the connector be exposed out of the receiving space, the fixing portion engages in the second engaging hole.

8. The flash drive of claim 7, wherein the connector is a universal serial bus connector.

9. The flash drive of claim 7, further comprising a resilient member connected between the main body and the fixing portion, to bias the fixing portion to move to engage in either the first engaging hole or the second engaging hole.

10. The flash drive of claim 9, wherein the resilient member is a coil spring.

11. The flash drive of claim 10, wherein the main body comprises a holder comprising a bottom wall, and a cover covered on the holder, the cover comprises a top wall defining a through hole, a post extends up from the bottom wall and axially defines a receiving hole to receive a first end of the spring, a first end of the fixing portion is fixed to a second end of the spring opposite to the holder, a second end of the fixing portion extends through the through hole to engage in either the first engaging hole or the second engaging hole.

12. The flash drive of claim 11, wherein the fixing portion comprises a connection portion, a projection and a pin respectively extends from opposite sides of the connection portion, the projection is fixed to the second end of the spring, the pin extends through the through hole, opposite ends of the spring respectively contact the bottom wall and the connection portion.

13. The flash drive of claim 7, wherein two slide slots are defined in inner surfaces of opposite sides of the casing, communicate with the receiving space, two poles extend from opposite sides of the main body to be slidably engaged in the corresponding slide slots.

14. The flash drive of claim 7, wherein an operation portion is formed on a second end of the main body opposite to the connector.
